(19) United States
(12) Patent Application Publication
(10) Pub. No.: US 2015/0103486 A1
(43) Pub. Date: Apr. 16, 2015

(54) Phase Change Module and Electronic Device Mounted with Same

(71) Applicant: Hitachi, Ltd., Tokyo (JP)

(72) Inventors: Yoshihiro KONDOU, Tokyo (JP); Fumio TAKEDA, Tokyo (JP); Shigemasa SATO, Tokyo (JP); Shigeyasu TSUBAKI, Tokyo (JP); Takayuki FUJIMOTO, Tokyo (JP)

(21) Appl. No.: 14/509,522

(22) Filed: Oct. 8, 2014

(30) Foreign Application Priority Data
Oct. 11, 2013 (JP) 2013-213295

(51) Int. Cl. H05K 7/20; F28D 15/04

(52) U.S. Cl. CPC H05K 7/20309; F28D 15/04; H05K 7/20136; H05K 7/20336; H05K 7/20409
USPC 361/679.47; 165/104.26

(57) ABSTRACT

To provide a phase change module as a cooling system capable of saving energy and miniaturizing of the cooling system utilizing a thermo siphon, and an electronic device suitable to mounting such a phase change module.

The phase change module 300 includes a jacket case 312 attached with an evaporator surface 311 with the evaporator surface 311 being arranged on a heat generating body, a radiator case 321 attached with cooling fins (radiator) 322 arranged at a position departing from the heat generating body, and a connecting plate 330 that connects the jacket case 312 and the radiator case 321, in which holes are bored in the connecting plate 330 at a position where the jacket case 312 and the radiator case 321 overlap.

### CLAIM OF PRIORITY

The present application claims priority from Japanese Patent application serial No. 2013-213295, filed on Oct. 11, 2013, the content of which is hereby incorporated by reference into this application.

### FIELD OF THE INVENTION

The present invention relates to a cooling system of an electronic device mounted with a heat generation source such as a CPU and the like inside a case of a server, storage device, network device and the like, and relates more specifically to a phase change module as a cooling system capable of saving energy and miniaturizing of the cooling system utilizing a thermo siphon and an electronic device suitable to mounting such a phase change module.

### BACKGROUND OF THE INVENTION

In recent years, in an electronic device represented by a server and the like, because of improvement of the processing speed and so on, plurality of so-called semiconductor devices such as central processing units (CPU) and the like are mounted on a circuit board, and it is configured that such a circuit board is mounted inside a box-shape rack with high density along with plurality of hard disk devices and the like.

In the meantime, with respect to the semiconductor devices such as the CPU described above, in general, when the temperature exceeds a predetermined level, not only that the performance thereof cannot be maintained but also the semiconductor device may possibly be broken in some cases. Therefore, the temperature control by cooling and so on is required, and a technology for efficiently cooling the semiconductor device whose heat generation amount increases is strongly required.

In such a technical background, with respect to the cooling device for cooling the semiconductor devices (CPU and the like) whose heat generation amount increases, high cooling performance capable of efficiently cooling such a semiconductor devices is required. Also, so far, with respect to the electronic device such as a server and the like, air-cooled type cooling devices have been often employed in general, however they are approaching the limit already because of the situations described above. Therefore, a cooling system of a new method is expected, and a cooling system utilizing a coolant such as the water and the like for example is watched as an example thereof.

Also, with respect to prior arts related to the present invention, for example in JP-A 2002-164486, a configuration for cooling a semiconductor element and the like is shown in which a boiling section including a heat receiving wall contacting a heat generating body and a cooling section including cooling fins are configured to be integrated and to overlap, and a flow passage for a coolant gas and a flow passage for a cooled liquid coolant are arranged in the overlapping section thereof. Further, in JP-A 2012-237491, a configuration is shown in which a coolant inside a container surrounded by two flat sheets is boiled by a heat generating body on the outer wall surface of one sheet and is cooled by a cooling section of cooling fins, the evaporation section and the cooling section continue to each other, and a gas flow passage section and a liquid returning flow passage section are integrated. Also, in JP-A 2004-132555, a configuration is shown in which, in a cooling device for semiconductor element and the like formed by a heat spreader, an evaporation section case and a condensing section case are connected to each other without overlapping with each other in the lateral direction, and a gas flow passage section and a liquid returning flow passage section are arranged separately. Further, in JP-A 2000-091482, a configuration is shown in which a boiling section attached with a semiconductor element and a condensing section attached with cooling fins on the outer wall are provided separately and are connected to each other in the vertical direction, and a gas flow passage section and a liquid returning flow passage section are integrated. Also, in JP-A Heisei 07-030023, a configuration of a cooling device for semiconductor element is shown in which an evaporating section receiving heat from a heat generating body and a condensing section attached with cooling fins are connected to each other vertically by an adiabatic section, and a gas flow passage section and a liquid returning flow passage section are separated inside the adiabatic section.

In the prior arts described above, in JP-A 2002-164486 to JP-A Heisei 07-030023, the configuration of the overlapping condition of the evaporating section and the condensing section has not been clarified, no mention has been made and no consideration has been made for such a structure that the gas flow and the liquid returning flow determining the magnitude of the heat transfer performance of the phase change do not affect each other.

### SUMMARY OF THE INVENTION

In order to solve the problem described above, the phase change module of the present invention is characterized to include a jacket case attached with an evaporator surface with the evaporator surface being arranged on a heat generating body employed, a radiator case attached with cooling fins arranged at a position departing from the heat generating body, and a connecting plate that connects the jacket case and the radiator case, in which holes are bored in the connecting plate at a position where the jacket case and the radiator case overlap.

Also, the phase change module of the present invention is characterized in that the holes arranged in the connecting plate includes a gas passing hole and a returning liquid passing hole.

Also, the phase change module of the present invention is characterized in that the returning liquid passing hole is arranged on the side closer to the cooling fins of the gas passing hole.

Also, the phase change module of the present invention is characterized in that a plurality of the evaporator surfaces and one set of cooling fins are provided.

Also, the phase change module of the present invention is characterized in that the connecting plate includes a wick.

Also, the phase change module of the present invention is characterized in that the connecting plate includes attaching holes for mounting on the heat generating body.

Also, the phase change module of the present invention is characterized in that the gas passing hole includes a gas ejection guide plate and the returning liquid passing hole includes a liquid returning guide plate.

Also, the phase change module of the present invention is characterized in that the jacket case includes a plurality of the evaporator surfaces.

Also, the phase change module of the present invention is characterized in that the connecting plate includes fins.

Also, in order to solve the problem described above, the electronic device of the present invention includes a phase change module including a jacket case attached with an evaporator surface with the evaporator surface being arranged on a heat generating body, a radiator case attached with cooling fins arranged at a position departing from the heat generating body, and a connecting plate that connects the jacket case and the radiator case, in which holes are bored in the connecting plate at a position where the jacket case and the radiator case overlap, in which the heat generating body is cooled by making an air flow hit the radiator case.

Also, the electronic device of the present invention is characterized in that an air flow by a plurality of cooling fans is made to hit the radiator case.

Also, the electronic device of the present invention is characterized to include a plurality of phase change modules, in which an air flow by a plurality of cooling fans is made to hit a plurality of the radiator case.

Also, the electronic device of the present invention is characterized in that an air flow is made to hit the radiator case by a cooling fan that cools a member other than the heat generating body.

By the configuration of the present invention described above, it becomes possible that the phase change module and the electronic device mounted with the same achieve a phase change module with the minimum component configuration of an evaporator surface, jacket case, radiator case, fins and connecting plate, and the cost of the thermo siphon can be reduced.

Also, by the configuration of the present invention described above, the phase change module and the electronic device mounted with the same can achieve to efficiently and surely execute cooling even without newly providing a cooling fan.

### BRIEF DESCRIPTION OF THE DRAWINGS

FIG. 1 is an overall construction drawing of the side view of the surrounding of a phase change module utilizing the thermo siphon of an embodiment of the present invention.

FIG. 2 is a top view of the phase change module.

FIG. 3 is a front view of the phase change module as viewed from the heat receiving jacket side.

FIG. 4 is aside view of the phase change module improving the heat receiving tolerance amount which is another embodiment of the present invention.

FIG. 5 is a top view of the phase change module in which mounting on a semiconductor device is considered which is another embodiment of the present invention.

FIG. 6 is aside view of the phase change module promoting the gas flow and the liquid returning flow which is another embodiment of the present invention.

FIG. 7 is a side view of the phase change module cooling two sets of semiconductor devices arranged in series which is another embodiment of the present invention.

FIG. 8 is a top view of the phase change module cooling two sets of semiconductor devices arranged in series which is another embodiment of the present invention.

FIG. 9 is a side view of the phase change module cooling two sets of semiconductor devices arranged in parallel which is another embodiment of the present invention.

FIG. 10 is a top view of the phase change module cooling two sets of semiconductor devices arranged in parallel which is another embodiment of the present invention.

FIG. 11 is an outside perspective view of a server, particularly a server mounted on a rack by plural numbers, as a representative example of an electronic device to which the phase change module utilizing the thermo siphon of the present invention is applied.

FIG. 12 is a perspective view showing a state a cover of the server is removed in order to show an example of the internal structure inside the server case.

FIG. 13 is a top view for explaining the arrangement state of the phase change module inside the server case.

FIG. 14 is a top view in which one set of the phase change module is applied to two sets of the semiconductor devices mounted in parallel which is another embodiment of the present invention.

FIG. 15 is a top view in which two sets of the phase change modules are applied respectively to two sets of the semiconductor devices mounted in parallel which is another embodiment of the present invention.

### DESCRIPTION OF THE PREFERRED EMBODIMENTS

Below, embodiments in the present invention will be described in detail using the drawings.

### First Embodiment

### Basic Configuration

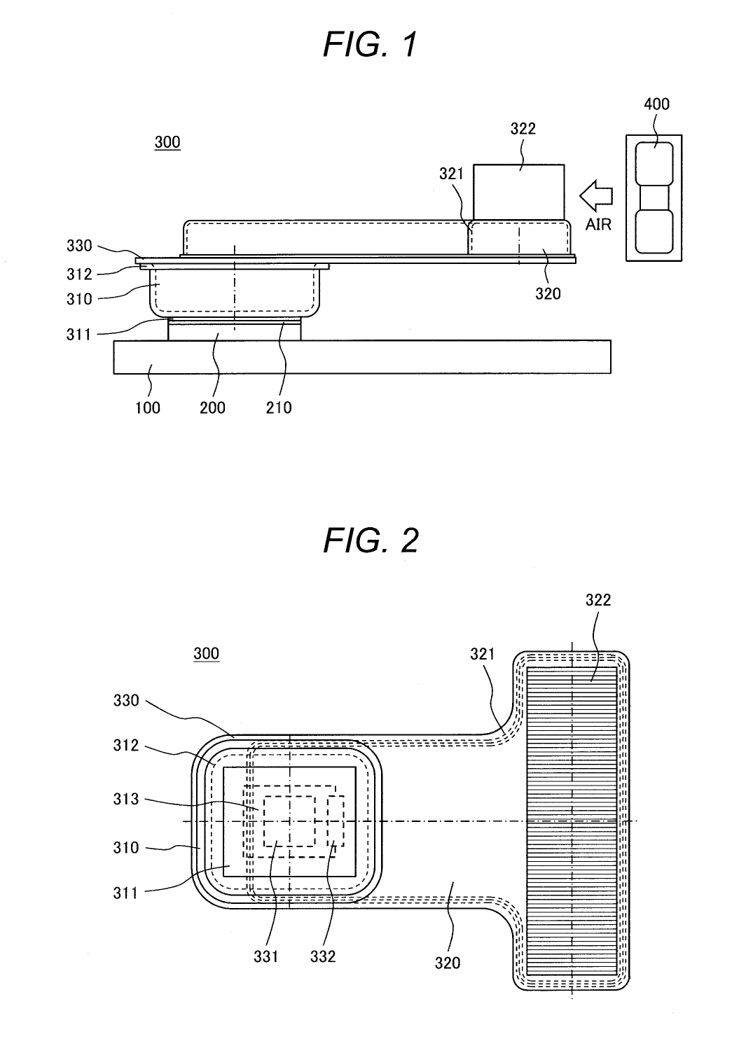

FIG. 1 shows an overall construction of the side view of the surrounding of a phase change module 300 utilizing the thermo siphon. In the drawing, the reference sign 100 shows a circuit board, and on the surface thereof, a semiconductor device 200 is mounted as a heat generating source such as a CPU for example. Also, to the surface of the semiconductor device 200, a heat receiving jacket 310 that constitutes a part of the phase change module 300 utilizing the thermo siphon of the present invention is attached. The heat receiving jacket 310 is formed of an evaporator surface 311 and a jacket case 312. The evaporator surface 311 is securely attached to the jacket case 312 by brazing and the like. More specifically, so-called thermal grease 210 is coated on the surface of the semiconductor device 200 in order to secure excellent thermal bonding with the evaporator surface 311, and the bottom surface of the evaporator surface 311 is made to contact the surface of the semiconductor device 200 and is fixed by fixing implements (not illustrated) such as screws and the like. Further, although the detailed structure of the phase change module 300 will be described below, the phase change module 300 includes a condenser 320 that includes a radiator case 321 and fins 322 along with the heat receiving jacket 310, and the heat receiving jacket 310 and the condenser 320 are attached to each other through a connecting plate 330. A gas hole and a liquid returning hole are arranged in the connecting plate 330 at a position where the jacket case 312 and the radiator case 321 overlap although these holes are not illustrated here. Also, the inside of the phase change module 300 is maintained to a reduced (low) pressure state of approximately 1/10 of the atmospheric pressure.

The heat receiving jacket 310 constitutes the boiling section, and the condenser 320 constitutes the condensing section respectively. Thereby, as described below also, the so-called thermo siphon is constituted which can circulate a liquid coolant by phase change of the liquid coolant without external power such as an electric pump and the like.

In other words, in the phase change module 300 utilizing the thermo siphon whose summary was described above, the heat generated by the semiconductor device 200 which is the heat generating source is transferred to the evaporator surface 311 which is the boiling section through the thermal grease 210. As a result, in the boiling section, although it is not illustrated, the liquid coolant boils and evaporates under a reduced pressure by the heat transferred, and the gas generated is led from the heat receiving jacket 310 to the condenser 320. Also, in the condensing section, the coolant gas is cooled by the air blown by a cooling fan 400 and the like, thereby becomes liquid, and thereafter returns to the heat receiving jacket 310 again along the connecting plate 330 by gravity.

Here, although the structure of the heat receiving jacket 310 will not be illustrated, the evaporator surface 311 formed of a metal sheet excellent in thermal conductivity such as copper, aluminum and the like for example is bonded by pressure welding and the like for example to the jacket case 312 which is obtained by drawing a metal such as copper, aluminum and the like into a bowl shape and arranging holes so that the evaporator surface 311 can be attached.

Also, a vaporization promoting plate 313 provided with the porous structure surface exerts stable evaporation performance (vaporization performance) unless the liquid coolant exhausts. Further, when the input calorie is less, the vaporization promoting plate 313 is impregnate with the liquid coolant and the pores of the porous material are filled with the liquid coolant, however when the input calorie is much, the liquid coolant filling the pores evaporates and becomes less, and therefore the portion with thin coolant liquid film increases inside the porous material. Accordingly, evaporation is further promoted, a state of increased heat radiation performance is achieved, and the heat transport amount increases. In other words, as the input calorie increases, evaporation is promoted depending on the temperature and evaporation is promoted depending increase of the gas amount, and therefore as the input calorie is more, the heat transport amount greatly increases and the efficiency improves.

Also, such an evaporator surface 311 is attached to the jacket case 312 that constitutes the heat receiving jacket 310 by welding and the like with a hole being bored in the heat receiving jacket 310, however, the present invention is not limited to it, and the evaporator surface 311 described above may be formed directly on the outer wall surface of a copper sheet that constitutes the bottom jacket case 312.

FIG. 2 shows a top view of the phase change module 300. In the evaporator surface 311, there is a vaporization promoting plate 313 promoting boiling generally in the center. The vaporization promoting pate surface 313 includes minute uneven projections and holes which are not illustrated. The connecting plate 330 includes a gas hole 331 and a liquid returning hole 332. The gas hole 331 is arranged at a position generally same to the center of the vaporization promoting plate 313 of the evaporator surface 311, and the liquid returning hole 332 is arranged in the vicinity of the end of the vaporization promoting plate 313 and on the side closer to the fins 322 and the condenser side. In other words, the liquid returning hole 332 is located on the side closer to the condenser 320 than the gas hole 331, and it is configured that the liquid can be returned efficiently.

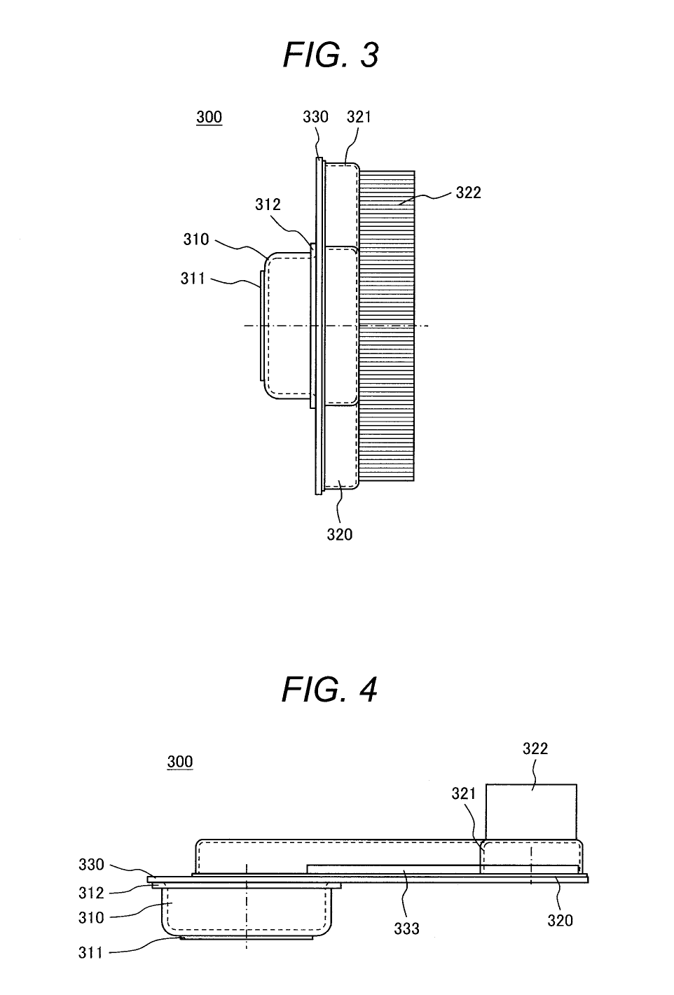

FIG. 3 shows a front view of the phase change module 300 as viewed from the heat receiving jacket 310 side. The width of the radiator case 321 is larger than the width of the jacket case 312. Thus, the area of the fins 322 attached to the radiator case 321 can be made large, and the cooling performance can be improved.

### Second Embodiment

### Wick in Connecting Plate

FIG. 4 shows a side view of the phase change module 300 improving the heat receiving tolerance amount which is another embodiment. A wick 333 is arranged in the connecting plate 330. The wick 333 is formed of a strand wire of a metal fine wire, a mesh screen and the like. The length of the wick 333 is the length from the position of the fins 322 of the condenser 320 to the liquid returning hole which is not illustrated. Because the wick 333 is arranged, the liquid coolant can be led to the liquid returning hole without that the flow of the coolant gas of a highspeed impedes the liquid returning flow. Thus, the liquid coolant can be sufficiently supplied to the evaporator surface 311, and the heat receiving tolerance amount from the semiconductor device can be improved.

### Third Embodiment

### Screw Holes in Connecting Plate

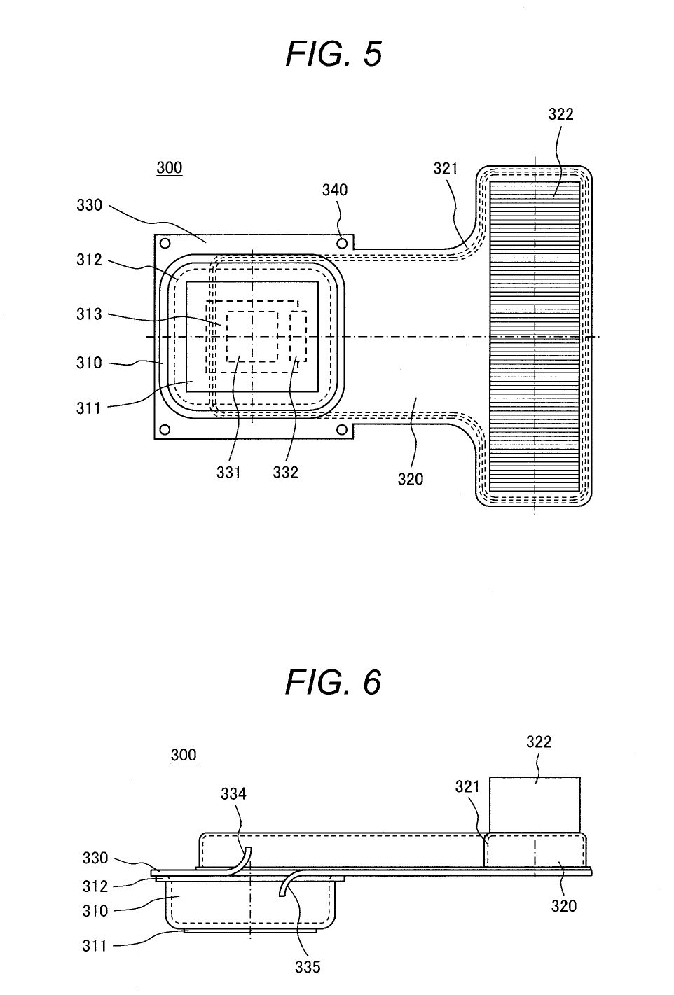

FIG. 5 shows a top view of the phase change module 300 in which mounting on a semiconductor device is considered which is another embodiment. In the connecting plate 330, screw attaching holes 340 for mounting on the semiconductor device are arranged. The screw attaching holes 340 are arranged at positions corresponding to the screw holes which are arranged in the circuit board. Thus, the phase change module 300 can be stably mounted on the semiconductor device.

### Fourth Embodiment

### Gas Ejection Guide Plate and Liquid Returning Guide Plate in Gas Hole and Liquid Returning Hole of Connecting Plate Respectively

FIG. 6 shows a side view of the phase change module 300 promoting the gas flow and the liquid returning flow which is another embodiment. A gas ejection guide plate 334 and a liquid returning guide plate 335 are arranged in the gas hole and the liquid returning hole of the connecting plate 330 respectively. Although they can be formed integrally by perforating and bending work of the connecting plate 330, it is also possible to form them by brazing a separate member.

### Fifth Embodiment

### Plural Evaporator Surfaces

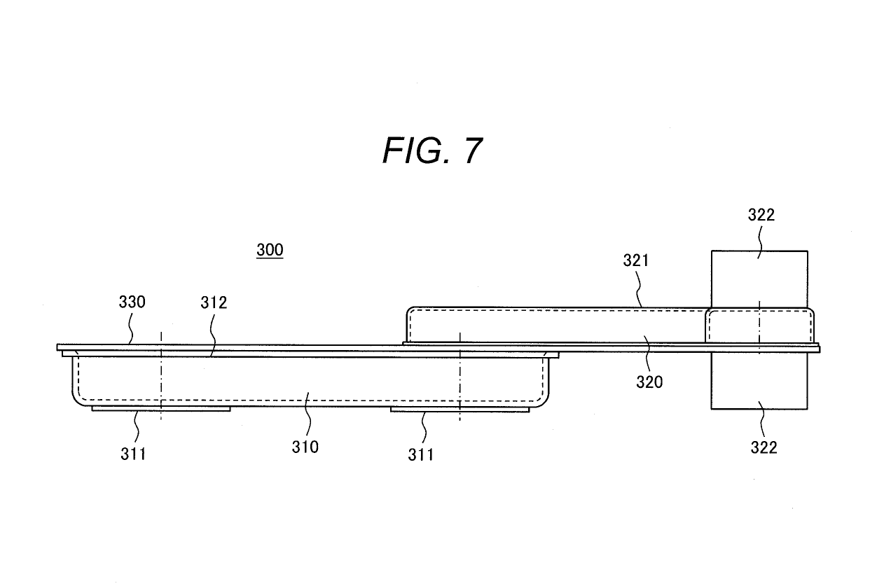

FIG. 7 shows a side view of the phase change module 300 cooling two sets of the semiconductor devices arranged in series which is another embodiment. In the heat receiving jacket 310, the evaporator surfaces 311 for cooling two sets of the semiconductor devices are arranged in two positions corresponding to the semiconductor devices. In the condenser 320, in addition to that the fins 322 are arranged in the radiator case 321 similarly to the above, another set of the fins 322 are attached to the connecting plate 330. By these two sets of the fins 322, two sets of the semiconductor devices can be cooled sufficiently.

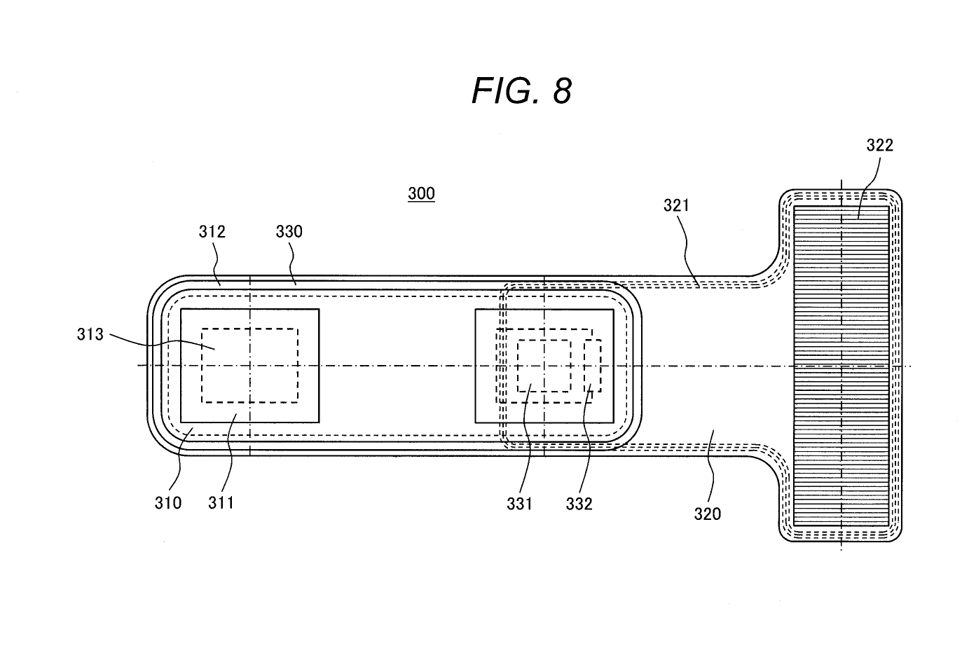

FIG. 8 shows a top view of the phase change module 300 cooling two sets of the semiconductor devices arranged in series. In the connecting plate 330, the gas hole 331 and the liquid returning hole 332 are arranged at the position of the evaporator surface 311 on the side closer to the condenser 320. Also, the liquid returning hole 332 is arranged on the side closer to the fins 322 of the condenser 320 than the gas hole 331. By these gas hole 331 and liquid returning hole 332, the gas generated in two evaporator surfaces 311 of the heat receiving jacket 310 passes through the gas hole 331, goes to the condenser 320 and is cooled by the fins 322, the liquefied coolant flows to the heat receiving jacket 310 through the liquid returning hole 332, and the liquid coolant can be supplied to two evaporator surfaces 311. Thus, stable cooling performance can be secured for two evaporator surfaces 311 also.

### Sixth Embodiment

### Another Set of Fins in Connecting Plate

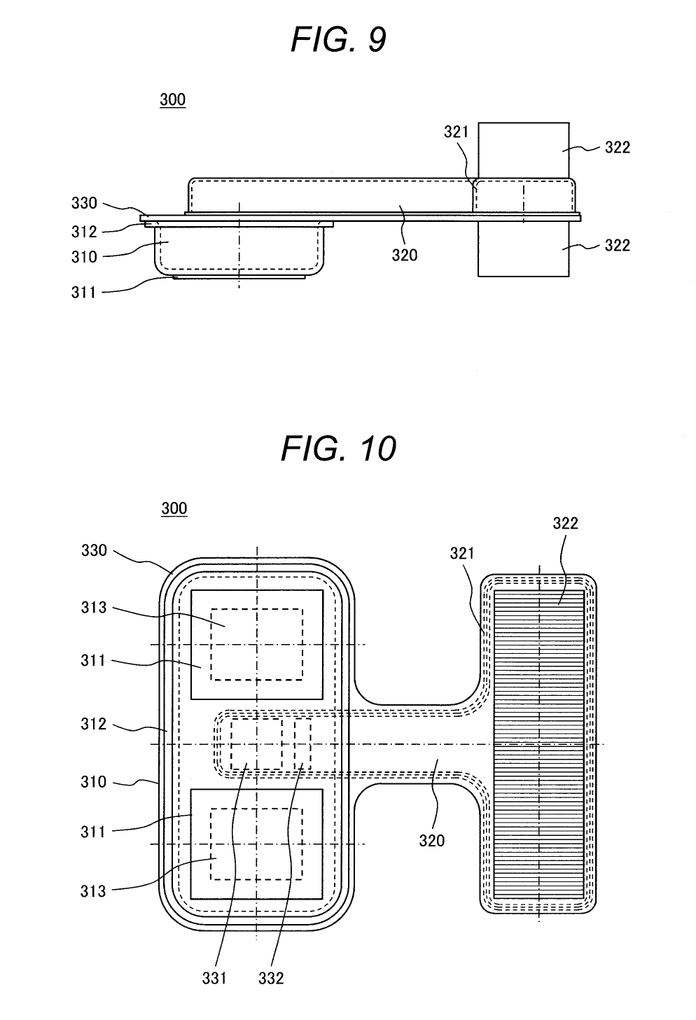

FIG. 9 shows a side view of the phase change module 300 cooling two sets of the semiconductor devices arranged in parallel which is another embodiment. In the condenser 320, in addition to that the fins 322 are arranged in the radiator case 321 similarly to the above, another set of the fins 322 are attached to the connecting plate 330. By these two sets of the fins 322, two sets of the semiconductor devices can be cooled sufficiently.

FIG. 10 shows a top view of the phase change module 300 cooling two sets of the semiconductor devices arranged in parallel. In the connecting plate 330, the gas hole 331 and the liquid returning hole 332 are arranged at a position in the middle of the evaporator surfaces 311 arranged in parallel. Also, the liquid returning hole 332 is arranged on the side closer to the fins 322 of the condenser 320 than the gas hole 331. By these gas hole 331 and liquid returning hole 332, the gas generated in two evaporator surfaces 311 of the heat receiving jacket 310 passes through the gas hole 331, goes to the condenser 320 and is cooled by the fins 322, the liquefied coolant flows to the heat receiving jacket 310 through the liquid returning hole 332, and the liquid coolant can be supplied to two evaporator surfaces 311. Thus, stable cooling performance can be secured for two evaporator surfaces 311 also.

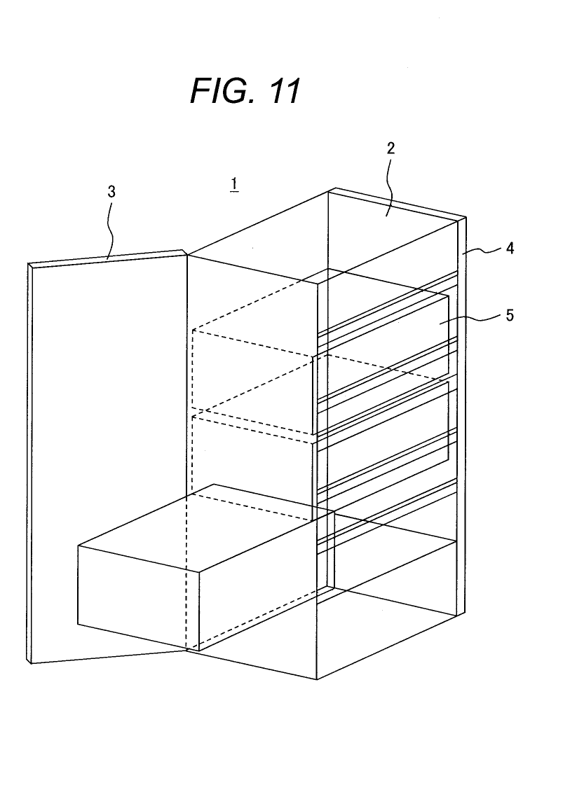

Next, examples of employing the phase change module utilizing the thermo siphon described above for electronic devices will be described below in detail referring to FIGS. 11-15 attached.

### Seventh Embodiment

### Application to Electronic Device

First, FIG. 11 attached shows an outside perspective view of servers, particularly servers mounted on a rack by plural numbers, as a representative example of an electronic device to which the phase change module utilizing the thermo siphon of the present invention is applied. In the drawing, a rack 1 includes a case 2 and covers 3, 4 (3 is a front door, 4 is aback door), and, inside thereof, plural server cases 5 formed in a predetermined shape and dimension are detachably arranged.

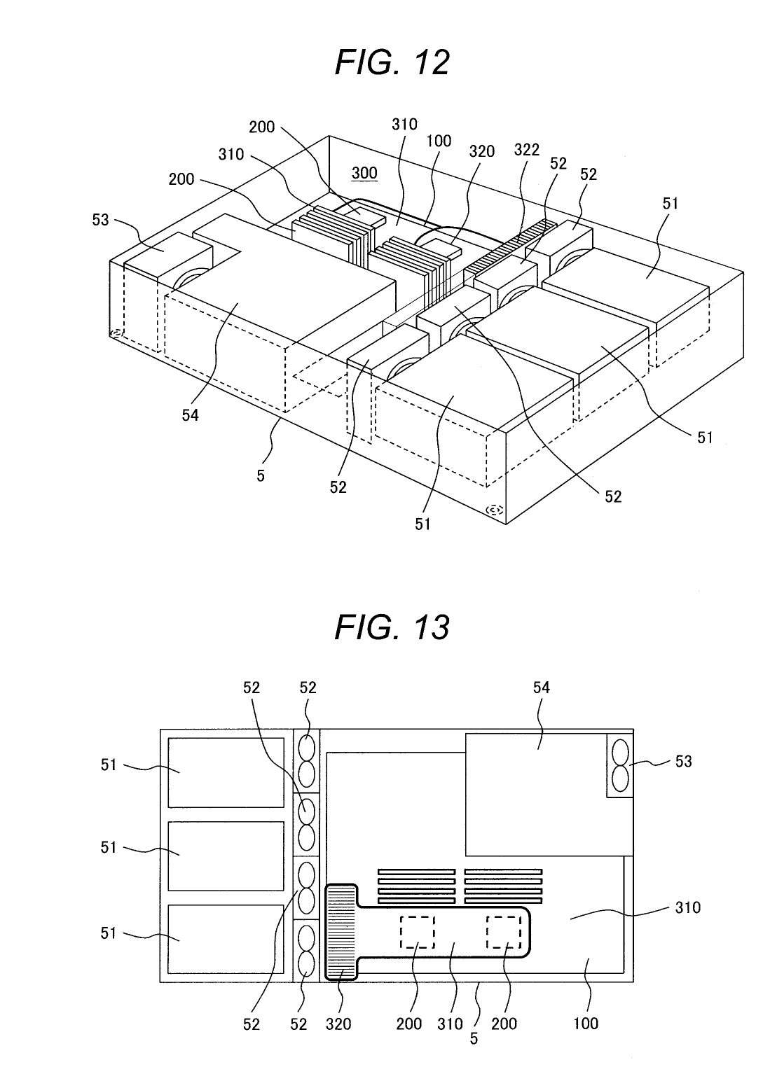

In the inside of each of these plural server cases 5, in general, as shown in attached FIGS. 12 and 13 for example, a plurality of (three sets in the present embodiment) hard disk drives 51 which are storage devices of a large capacity are arranged on one face (on the front side shown in the right side of FIG. 12 in the present embodiment) considering the maintainability thereof, and, behind them, a plurality of (four sets in the present embodiment) cooling fans 52 for cooling these hard disk drives are attached which also become heat generation sources inside the case. Also, in the space between the other face of the server case 5 (that is the space behind), a block 54 storing a LAN and the like which is an interface of the electric source and the communication means is arranged also along with a cooling fan 53. Further, in the remaining space, the circuit board 100 mounted with plurality of (two sets in series in the present embodiment) the semiconductor devices 200 (CPU for example) which are the heat generation sources are arranged. Further, this perspective view of FIG. 12 shows a state the covers thereof have been removed.

Furthermore, as it is clear in this drawing also, in each semiconductor device (CPU) 200, the phase change module 300 utilizing the thermo siphon of the present invention described above is arranged. More specifically, to the surface of each semiconductor device (CPU) 200, the bottom surface of the heat receiving jacket 310 is made to contact through the thermal grease coated therebetween, and thereby excellent thermal bonding is secured. Also, according to the present invention, the condenser 320 constituting the phase change module 300 is arranged behind four sets of the cooling fans 52 for air-cooling the hard disk drive. In other words, the condenser 320 constituting the phase change module is arranged along the passage of the air (cooling air) supplied from the outside by the cooling fans 52. More specifically, the condenser 320 is attached so as to be arrayed side by side in parallel with the row of the cooling fans 52.

Thus, in the structure of the electronic device described above, the cooling fan 52 that is the cooling means for other devices incorporated in the case 5 is utilized (or co-used) as the cooling means (fins) for the condenser 320 that constitutes the phase change module 300 utilizing the thermo siphon of the present invention. Thereby, it becomes possible to efficiently and surely cool the semiconductor device (CPU) 200 that is the heat generation source inside the case without having an exclusive cooling fan, or in other words, by a cooling system comparatively simple and inexpensive, not requiring the pump power for liquid driving, and excellent in energy saving. Also, by utilizing the phase change module 300 that utilizes the thermo siphon of the present invention, arrangement with high degree of freedom becomes possible even for the electronic device such as a server and the like which has comparatively high heat exchange efficiency and in which high density mounting is required because of its comparatively simple structure.

Further, as it is clear from the embodiment described above also, the condenser 320 constituting the phase change module 300 is arranged so as to cover the exhaust face of a plurality of (two sets in series in the present embodiment) cooling fans. Also, according to such a configuration, even when any cooling fan may stop due to the failure, cooling of the condenser 320 is continued by the cooling air generated by the remaining cooling fans, which means redundancy can be secured, and therefore such a configuration is suitable as the structure of a cooling system for electronic devices. When the condenser 320 is brought closer to the side of the cooling fan having small area opposing the condenser, redundancy thereof can be further improved for the stop caused by the failure of any cooling fan.

In the present embodiment, 1.5 set of the cooling fan is used for the condenser of the thermo siphon of one set. At this time, when one set of the cooling fan stops, only the remaining 0.5 set of the cooling fan comes to execute cooling, and it becomes the situation equal to that ⅔ portion of the radiator of the thermo siphon condenser cannot cool. Ina server system, because it takes some time for normal completion of the system in an emergency, cooling performance should be secured for the duration. In a radiator of the water-cooling system of a prior art, because the coolant flows uniformly over the entire radiator, when the effective radiation area reduces by ⅔, cooling performance of the coolant comes to drop by that portion, and this portion of the drop of the cooling performance comes to directly contribute to the temperature rise of the CPU. However, in the phase change module of the thermo siphon, because the gas has a high flow speed, it flushes away the liquid film in the condenser 320 and contributes to improvement of the condensing performance. Therefore, drop of the radiation performance when one set of the cooling fan stops can be suppressed more. Accordingly, by utilizing the thermo siphon, redundancy can be secured with less number of sets of fans.

### Eighth Embodiment

### Cooling by Plural Cooling Fans

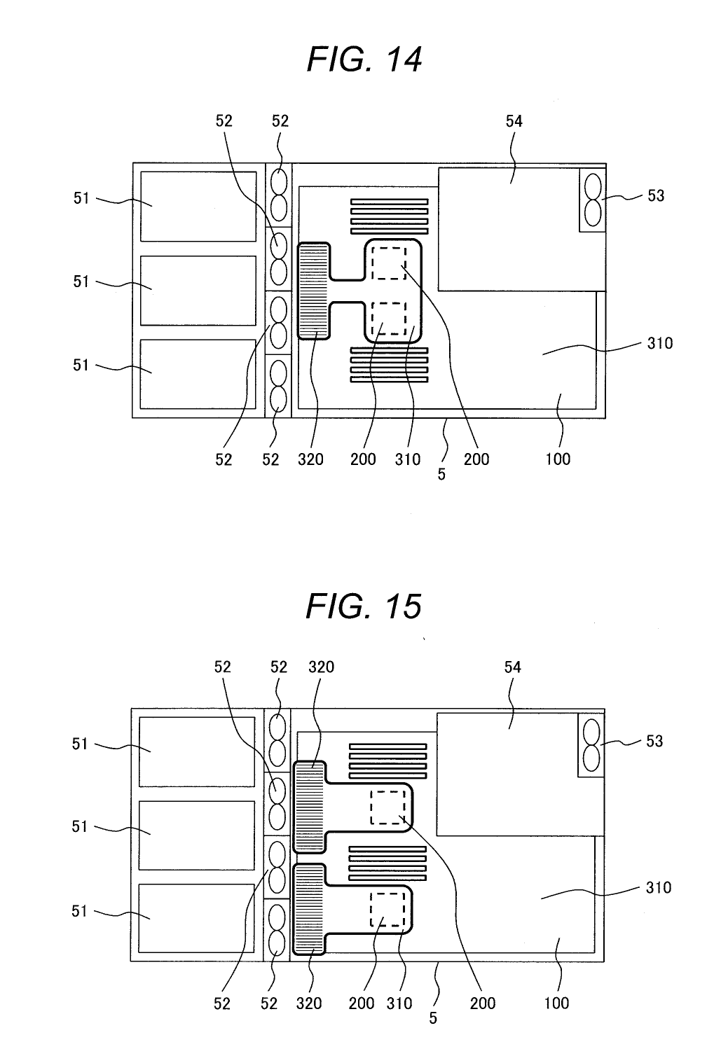

FIG. 14 shows an embodiment of application of the phase change module when the semiconductor devices (CPU) 200 are mounted in parallel on the circuit board 100. As it is clear from the drawing also, the condenser 320 constituting the phase change module 300 is arranged so as to cover the exhaust face of a plurality of (two sets in parallel in the present example) cooling fans. Also, according to such a configuration, even when any cooling fan may stop due to the failure, cooling of the condenser 320 is continued by the cooling air generated by the remaining cooling fans, which means redundancy can be secured, and therefore such a configuration is suitable as the structure of a cooling system for electronic devices. When the condenser 320 is brought closer to the side of the cooling fan having small area opposing the condenser, redundancy thereof can be further improved for the stop caused by the failure of either cooling fan.

### Ninth Embodiment

FIG. 15 shows an embodiment of application of another phase change module when the semiconductor devices (CPU) 200 are mounted in parallel on the circuit board 100. As it is clear from the drawing also, in each semiconductor device (CPU) 200, the phase change module 300 utilizing the thermo siphon of the present invention described above is arranged respectively. More specifically, to the surface of the semiconductor device (CPU) 200, the bottom surface of the heat receiving jacket 310 is made to contact through the thermal grease coated therebetween, and thereby excellent thermal bonding is secured. Also, according to the present invention, the condenser 320 constituting the phase change module 300 and including offset fins is arranged behind four sets of cooling fans 52 for air-cooling the hard disk drive. In other words, the condenser 320 constituting the phase change module is arranged side by side along the passage of the air (cooling air) supplied from the outside by the cooling fans 52. More specifically, the condenser 320 including the offset fins is attached so as to be arrayed side by side in parallel with the row of the cooling fans 52.

Thus, in the structure of the electronic device described above, the cooling fan 52 that is the cooling means for other devices incorporated in the case 5 is utilized (or co-used) as the cooling means (radiator) for the condenser 320 that constitutes the phase change module 300 utilizing the thermo siphon of the present invention. Thereby, it becomes possible to efficiently and surely cool the CPU 200 that is the heat generation source inside the case without having an exclusive cooling fan, or in other words, by the phase change module comparatively simple and inexpensive, not requiring the pump power for liquid driving, and excellent in energy saving. Also, by utilizing the phase change module 300 that utilizes the thermo siphon of the present invention, arrangement with high degree of freedom becomes possible even for the electronic device such as a server and the like which has comparatively high heat exchange efficiency and in which high density mounting is required because of its comparatively simple structure.

Further, as it is clear from the embodiment described above also, the condenser 320 constituting the phase change module 300 is arranged so as to cover the exhaust face of a plurality of (two sets in the present example) cooling fans respectively. Also, according to such a configuration, even when any cooling fan stops due to the failure, cooling of the condenser 320 is continued by the cooling air generated by the remaining cooling fans, which means redundancy can be secured, and therefore such a configuration is suitable as the structure of the phase change module for electronic devices.

In the present embodiment, three sets of the cooling fan are used for two sets of the condensers of the thermo siphon, and 1.5 sets of the cooling fan corresponds to one set of the condenser. At this time, when one set of the cooling fan stops, only the remaining 0.5 set of the cooling fan comes to execute cooling, and it becomes the situation equal to that ⅔ portion of the radiator of the thermo siphon condenser cannot cool. In a server system, because it takes some time for normal completion of the system in an emergency, cooling performance should be secured for the duration. In a radiator of the water-cooling system of a prior art, because the coolant flows uniformly over the entire radiator, when the effective radiation area reduces by ⅔, cooling performance of the coolant comes to drop by that portion, and this portion of the drop of the cooling performance comes to directly contribute to the temperature rise of the CPU. However, in the phase change module of the thermo siphon, because the gas has a high flow speed, it flushes away the liquid film in the condenser 320 and contributes to improvement of the condensing performance. Therefore, drop of the radiation performance when one set of the cooling fan stops can be suppressed more. Accordingly, by utilizing the thermo siphon, redundancy can be secured with less number of sets of fans.

### REFERENCE SIGNS LIST

1 . . . rack
2 . . . rack case
3, 4 . . . cover
5 . . . server case
100 . . . circuit board
200 . . . semiconductor device
210 . . . thermal grease
300 . . . phase change module
310 . . . heat receiving jacket
311 . . . evaporator surface
312 . . . jacket case
313 . . . vaporization promoting plate
320 . . . condenser
321 . . . radiator case
322 . . . fins
330 . . . connecting plate
331 . . . gas hole
332 . . . liquid returning hole
333 . . . wick
334 . . . gas ejection guide plate
335 . . . liquid returning guide plate
340 . . . screw attaching hole
400 . . . cooling fan

What is claimed is:

1. A phase change module, comprising:
a jacket case attached with an evaporator surface with the evaporator surface being arranged on a heat generating body;
a radiator case attached with cooling fins arranged at a position departing from the heat generating body; and
a connecting plate that connects the jacket case and the radiator case, wherein
holes are bored in the connecting plate at a position where the jacket case and the radiator case overlap.

2. The phase change module according to claim 1, wherein
the holes arranged in the connecting plate includes a gas passing hole and a returning liquid passing hole.

3. The phase change module according to claim 1, wherein
the returning liquid passing hole is arranged on the side closer to the cooling fins of the gas passing hole.

4. The phase change module according to claim 1, wherein
a plurality of the evaporator surfaces and one set of cooling fins are provided.

5. The phase change module according to claim 1, wherein
the connecting plate includes a wick.

6. The phase change module according to claim 1, wherein
the connecting plate includes attaching holes for mounting on the heat generating body.

7. The phase change module according to claim 1, wherein
the gas passing hole includes a gas ejection guide plate and the returning liquid passing hole includes a liquid returning guide plate.

8. The phase change module according to claim 1, wherein
the jacket case includes a plurality of the evaporator surfaces.

9. The phase change module according to claim 1, wherein
the connecting plate includes fins.

10. An electronic device mounted with the phase change module according to claim 1.

11. An electronic device comprising a phase change module that comprises:
a jacket case attached with an evaporator surface with the evaporator surface being arranged on a heat generating body;
a radiator case attached with cooling fins arranged at a position departing from the heat generating body; and
a connecting plate that connects the jacket case and the radiator case, wherein
holes are bored in the connecting plate at a position where the jacket case and the radiator case overlap, and
the heat generating body is cooled by making an air flow hit the radiator case.

12. The electronic device according to claim 11, wherein
an air flow by a plurality of cooling fans is made to hit the radiator case.

13. The electronic device according to claim 12, comprising:
a plurality of phase change modules, wherein
an air flow by a plurality of cooling fans is made to hit a plurality of the radiator case.

14. The electronic device according to claim 11, wherein
an air flow is made to hit the radiator case by a cooling fan that cools a member other than the heat generating body.
